(19) United States
(12) Patent Application Publication
(10) Pub. No.: US 2012/0153934 A1
(43) Pub. Date: Jun. 21, 2012

(54) VOLTAGE AND CURRENT SAMPLING DEVICE

(75) Inventors: Jiasheng WAN, Wuhan (CN); Zhiqiang WANG, Wuhan (CN)

(73) Assignee: HUBEI SHENGJIA ELECTRIC APPARATUS CO., LTD., Wuhan (CN)

(21) Appl. No.: 12/970,919

(22) Filed: Dec. 16, 2010

(51) Int. Cl. G01R 19/22

(52) U.S. Cl. 324/119; 324/120

(57) ABSTRACT

A voltage and current sampling device, including a box, a current transformer, and a voltage acquisition unit, including a voltage collection sub-unit, and a voltage/frequency conversion sub-unit. The current transformer is disposed in the box. A phase line passes through the center of the current transformer. The current transformer outputs a current signal via a current signal output end. The voltage collection sub-unit is disposed on the phase line whereby acquiring a real-time voltage signal and converting the real-time voltage signal into a first voltage sampling signal. The voltage/frequency conversion sub-unit is connected to the voltage collection sub-unit whereby converting the first voltage sampling signal into a first frequency signal.

### BACKGROUND OF THE INVENTION

1. Field of the Invention

The invention relates to a voltage and current sampling device.

2. Description of the Related Art

Voltage and current sampling devices are widely used in electric industry. However, there are several problems with conventional voltage and current sampling devices: volume thereof is big, and measurement accuracy thereof is not high enough.

### SUMMARY OF THE INVENTION

In view of the above-described problem, it is one objective of the invention to provide a voltage and current sampling device that is capable of addressing the above-mentioned problems.

To achieve the above objectives, in accordance with one embodiment of the invention, provided is a voltage and current sampling device, comprising a box, a current transformer, and a voltage acquisition unit, comprising a voltage collection sub-unit, and a voltage/frequency conversion sub-unit, the current transformer is disposed in the box, a phase line passes through the center of the current transformer, the current transformer outputs a current signal via a current signal output end, the voltage collection sub-unit is disposed on the phase line whereby acquiring a real-time voltage signal and converting the real-time voltage signal into a first voltage sampling signal, and the voltage/frequency conversion sub-unit is connected to the voltage collection sub-unit whereby converting the first voltage sampling signal into a first frequency signal.

In a class of this embodiment, it further comprises a voltage conversion unit connected to the current signal output end whereby converting output current therefrom into a second voltage sampling signal.

In a class of this embodiment, the voltage/frequency conversion sub-unit further operates to convert the second voltage sampling signal into a second frequency signal.

In a class of this embodiment, the voltage collection sub-unit comprises a voltage sampling portion, a voltage signal processing circuit, and a power circuit, the voltage sampling portion operates to collect a real-time voltage signal on the phase line, the voltage signal processing circuit operates to rectify the real-time voltage signal and to convert the real-time voltage signal into a first DC voltage sampling signal, and the power circuit operates to stabilize and filter the first DC voltage sampling signal, and to transform the first DC voltage sampling signal into power voltage.

In a class of this embodiment, the voltage sampling portion is a mechanical component, and comprises a conductive sampling sub-portion, and a fixing sub-portion, the conductive sampling sub-portion is made of conductive materials, and connected to the power line, or contacted with a core of the power line via an insulation slug, whereby acquiring the real-time voltage signal on the power line, and the fixing sub-portion operates to fix connection between the conductive sampling sub-portion and the power line.

In a class of this embodiment, as the power line has the insulation slug, the conductive sampling sub-portion is in the shape of a tooth, penetrates in the power line and is contacted with the core thereof.

In a class of this embodiment, the voltage signal processing circuit comprises a first voltage circuit operating to process the real-time voltage signal whereby generating the first voltage sampling signal, the first voltage circuit comprises a first resistor, a first voltage stabilizing tube, a rectifier bridge, the first voltage stabilizing tube is serially connected to the first resistor, the rectifier bridge is parallel connected to the first resistor, the real-time voltage signal is output from both ends of the first resistor, and the rectifier bridge operates to output the first voltage sampling signal.

In a class of this embodiment, the power circuit comprises a fourth resistor, a second voltage stabilizing tube, a first capacitor, and a second capacitor, the fourth resistor is serially connected to the rectifier bridge whereby reducing voltage, and the second voltage stabilizing tube, the first capacitor, and the second capacitor are parallel connected whereby implementing voltage stabilizing and filtering, and forming stabilized power output.

In a class of this embodiment, the voltage signal processing circuit comprises a first voltage circuit operating to process the real-time voltage signal whereby generating the first voltage sampling signal, the first voltage circuit comprises at least a pair of first resistors, and a rectifier bridge, the first resistors are serially connected to each other, and the rectifier bridge is parallel connected to one of the first resistors, and operates to output the first voltage sampling signal.

In a class of this embodiment, the voltage signal processing circuit comprises a first voltage circuit operating to process the real-time voltage signal whereby generating the first voltage sampling signal, the first voltage circuit comprises a first resistors, at least a pair of groups each comprising a first resistor and a capacitor, and a rectifier bridge, the groups are serially connected to each other, and the rectifier bridge is parallel connected to one of the groups, and operates to output the first voltage sampling signal.

In a class of this embodiment, the voltage signal processing circuit comprises a first voltage circuit operating to process the real-time voltage signal whereby generating the first voltage sampling signal, the first voltage circuit comprises a first resistors, at least a pair of capacitors, a rectifier bridge, the capacitors are serially connected to each other, and the rectifier bridge is parallel connected to one of the capacitors, and operates to output the first voltage sampling signal.

In a class of this embodiment, the voltage/frequency conversion sub-unit comprises an integrating circuit, and a voltage/frequency conversion circuit, the integrating circuit operates to integrate voltage of the first voltage sampling signal, and to convert the first voltage sampling signal into corresponding first current, and the voltage/frequency conversion circuit operates to receive the first current, and to output a first frequency corresponding to the voltage of the first voltage sampling signal.

In a class of this embodiment, the integrating circuit comprises a first integrator, an inverting input end of the first integrator acquires the first voltage sampling signal, and the power circuit provides operating voltage to the integrator.

In a class of this embodiment, the integrating circuit further comprises a fifth resistor, a third capacitor, a fifth capacitor, and a second diode, the fifth resistor is parallel connected to the third capacitor, one parallel connection end is connected to a non-inverting input end of the second integrator, and the other parallel connection end is connected to the ground, the fifth capacitor is serially connected to the second diode whereby preventing signal drift at an output end of the second integrator, an anode of the second diode is connected to the ground, and a connection point of the second diode and the fifth capacitor is connected to an output end of the first integrator.

In a class of this embodiment, the voltage/frequency conversion sub-unit comprises an integrating circuit, and a voltage/frequency conversion circuit, the integrating circuit operates to integrate voltage of the first voltage sampling signal and the second voltage sampling signal, and to respectively convert the first voltage sampling signal and the second voltage sampling signal into corresponding first current and second current, and the voltage/frequency conversion circuit operates to receive the first current and the second current, and to output a first frequency and a second frequency respectively corresponding to the voltage of the first voltage sampling signal and the second voltage sampling signal.

In a class of this embodiment, the integrating circuit comprises a first integrator, and a second integrator, an inverting input end of the first integrator acquires the first voltage sampling signal, an inverting input end of the second integrator acquires the second voltage sampling signal, and the power circuit provides operating voltage to the integrator and the second integrator.

Advantages of the invention comprise: volume thereof is small, and measurement accuracy thereof is high.

### BRIEF DESCRIPTION OF THE DRAWINGS

FIG. 1 is a schematic view of a voltage and current sampling device of an embodiment of the invention;

FIG. 2 is a schematic view of a voltage collection sub-unit of the invention;

FIG. 3 is a schematic diagram of a voltage and current sampling device of an embodiment of the invention;

FIG. 4 is a schematic view of a voltage and current sampling device of another embodiment of the invention;

FIG. 5 is a schematic view of another voltage collection sub-unit of the invention;

FIG. 6 is a schematic diagram of a voltage and current sampling device of another embodiment of the invention;

FIG. 7 is a schematic diagram of a voltage and current sampling device of a further embodiment of the invention;

FIG. 8 is a schematic diagram of a voltage and current sampling device of still another embodiment of the invention; and

FIG. 9 is a schematic diagram of a voltage and current sampling device of still further embodiment of the invention.

### DETAILED DESCRIPTION OF THE EMBODIMENTS

Further description will be given below in conjunction with accompanying drawings and specific embodiments.

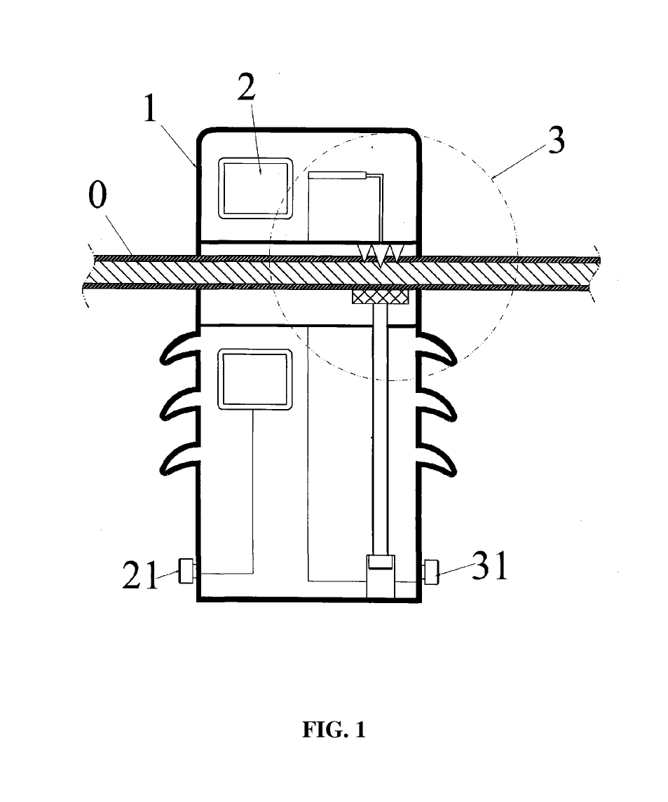

As shown in FIG. 1, a voltage and current sampling device of the invention comprises a box 1, a current transformer unit, and a voltage acquisition unit, comprising a voltage collection sub-unit 3, a circuit board, and a voltage/frequency conversion sub-unit.

The current transformer unit is disposed in the box 1, and comprises a current transformer 2, and a current signal output terminal 21.

A phase line 0 passes through the center of the current transformer 2.

A current signal generated by the current transformer 2 is output via the current signal output terminal 21 on the box 1.

The voltage collection sub-unit 3 is disposed on the phase line 0 whereby acquiring a real-time voltage signal and converting the real-time voltage signal into a first voltage sampling signal.

The voltage/frequency conversion sub-unit is disposed on the circuit board, and connected to the voltage collection sub-unit whereby converting the first voltage sampling signal into a first frequency signal. The first frequency signal is then output via the voltage signal output terminal 31 on the box 1.

The box 1 is made of insulating and self-extinguishing materials.

The voltage collection sub-unit 3 comprises a voltage sampling portion, a voltage signal processing circuit, and a power circuit. The voltage sampling portion operates to collect a real-time voltage signal on the phase line, the voltage signal processing circuit operates to rectify the real-time voltage signal and to convert the real-time voltage signal into a first DC voltage sampling signal, and the power circuit operates to stabilize and filter the first DC voltage sampling signal, and to transform the first DC voltage sampling signal into power voltage.

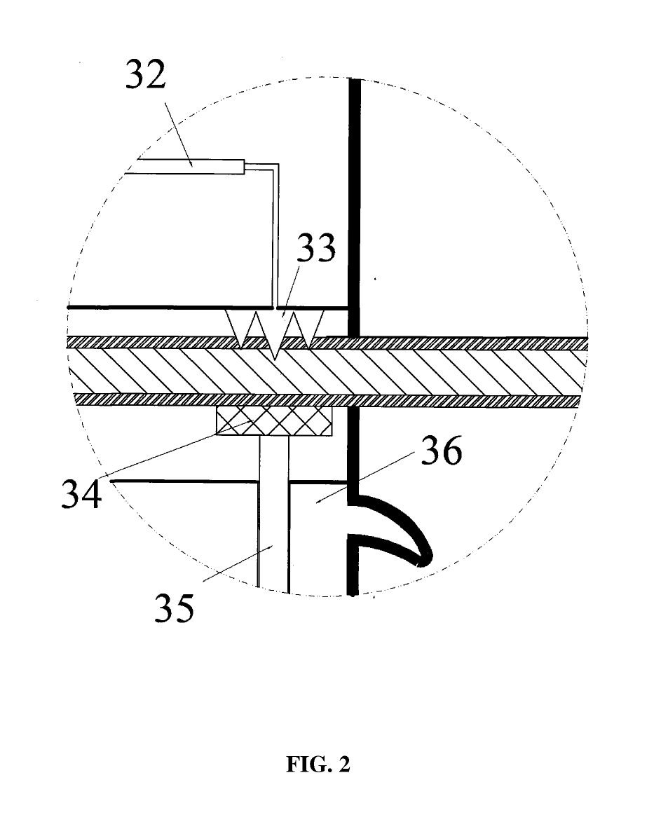

As shown in FIG. 2, the voltage sampling portion is a mechanical component, and comprises a conductive sampling sub-portion 33, and a fixing sub-portion. The conductive sampling sub-portion is made of conductive materials, and connected to the power line as the power line is metal bare wire, or contacted with a core of the power line as the power line has an insulation slug, whereby acquiring the real-time voltage signal on the power line, and the conductive sampling sub-portion is in the shape of a tooth so that it is capable of penetrating the insulation slug.

The fixing sub-portion comprises a fixing block 34 and a bolt 35. The fixing sub-portion is received in the box 1 via the bolt 35. The top of the bolt 35 abuts against the fixing block 34 whereby fixing connection between the conductive sampling sub-portion 33 and the power line.

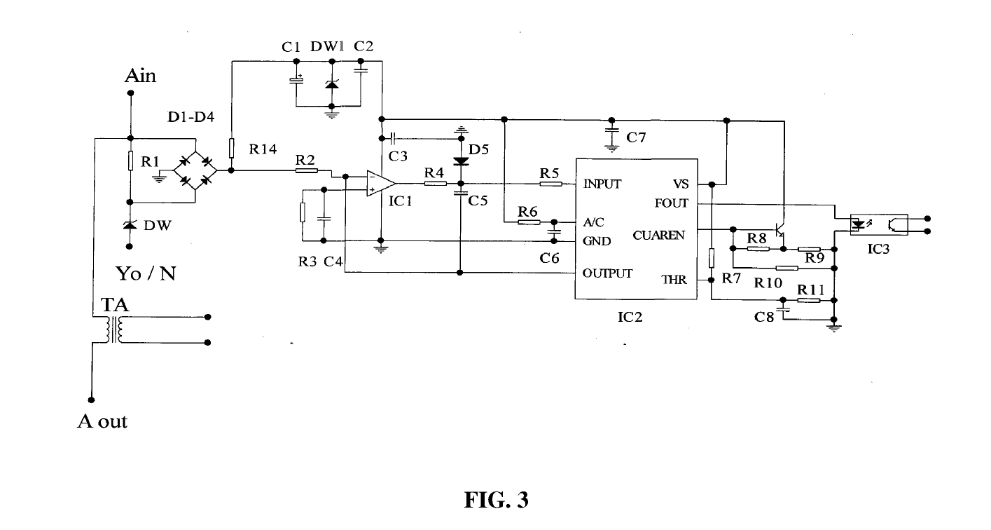

As shown in FIG. 3, a voltage signal processing circuit, a power circuit, and the voltage/frequency conversion sub-unit are disposed on the circuit board.

The voltage signal processing circuit comprises a first voltage circuit operating to process the real-time voltage signal whereby generating the first voltage sampling signal, the first voltage circuit comprises a first resistor R1, a first voltage stabilizing tube DW, a rectifier bridge D1-D4, the first voltage stabilizing tube DW is serially connected to the first resistor R1, the rectifier bridge D1-D4 is parallel connected to the first resistor R1, the real-time voltage signal is output from both ends of the first resistor R1, and the rectifier bridge D1-D4 operates to output the first voltage sampling signal.

The power circuit comprises a fourth resistor R14, a second voltage stabilizing tube DW1, a first capacitor C1, and a second capacitor C2, the fourth resistor R14 is serially connected to the rectifier bridge D1-D4 whereby reducing voltage, and the second voltage stabilizing tube DW1, the first capacitor C1, and the second capacitor C2 are parallel connected whereby implementing voltage stabilizing and filtering, and forming stabilized power output.

The voltage/frequency conversion sub-unit comprises an integrating circuit, a voltage/frequency conversion circuit, a reference voltage generating circuit, and an optoelectronic isolating device.

The integrating circuit comprises a first integrator IC1, a fifth resistor R3, a third capacitor C4, a fifth capacitor C5, and a second diode D5.

An inverting input end of the first integrator IC1 acquires the first voltage sampling signal via a second resistor R2, and the power circuit provides operating voltage to the first integrator. The first integrator operates to integrate voltage of the first voltage sampling signal, and to convert the first voltage sampling signal into corresponding first current.

The fifth resistor R3 is parallel connected to the third capacitor C4, one parallel connection end is connected to a non-inverting input end of the first integrator IC1, and the other parallel connection end is connected to the ground.

The fifth capacitor C5 is serially connected to the second diode D5 whereby preventing signal drift at an output end of the first integrator, an anode of the second diode D5 is connected to the ground, and a connection point of the second diode D5 and the fifth capacitor C5 is connected to an output end of the first integrator IC1.

The voltage/frequency conversion circuit operates to receive the first current, and to output a first frequency corresponding to the voltage of the first voltage sampling signal, and comprises a voltage/frequency conversion chip IC2. An input end of the voltage/frequency conversion chip IC2 acquires the current signal, and the power circuit provides operating voltage thereto.

The reference voltage generating circuit comprises a first triode, a sixth resistor R8, and a seventh resistor R9. A collecting electrode of the first triode is connected to the power circuit, and a base electrode thereof is connected to a reference voltage output end CUAREN of the voltage/frequency conversion chip IC2. The sixth resistor R8 is serially connected to the seventh resistor R9, one serial connection end is connected to the base electrode of the first triode, and the other end is connected to the ground, and a connection point of the sixth resistor R8 and the seventh resistor R9 is connected to an emitting electrode of the first triode.

The optoelectronic isolating device is connected to an output end FOUT of the voltage/frequency conversion chip IC2, and operates to convert the frequency signal into an electric signal. In this embodiment, the optoelectronic isolating device is a photo coupler IC3 with good anti-interference capability, which makes the invention suitable for long-distance transmission.

For the voltage and current sampling device of the first embodiment of the invention, during simultaneous acquisition of a voltage signal and a current signal from one phase line, to prevent electromagnetic interference between voltage transformers, direct acquisition via contacting and voltage/frequency conversion are used, which greatly improves measurement precision of voltage, and reduces power consumption of the voltage transformers. At this time, sampling of the current signal is implemented by acquiring and outputting an analog signal via a current transformer.

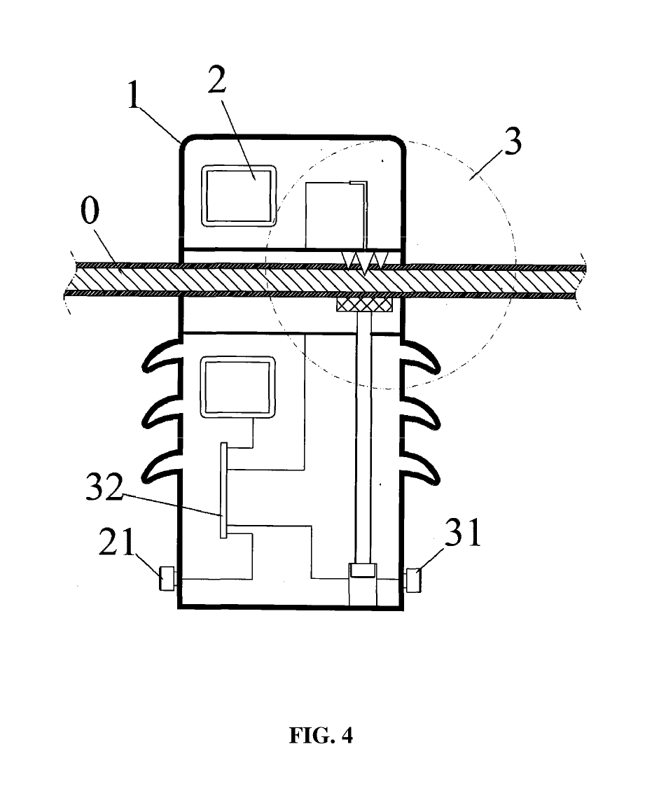

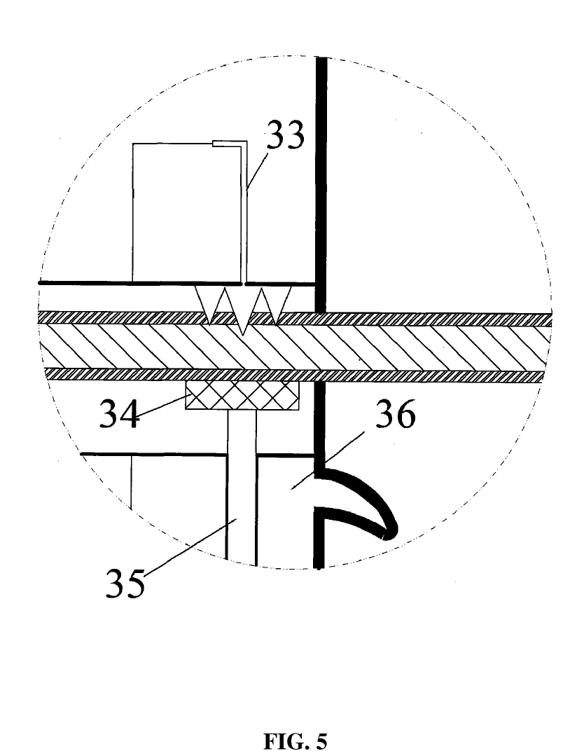

As shown in FIGS. 4 and 5, a voltage and current sampling device of a second embodiment of the invention is almost the same as that of the above-mentioned first embodiment, except that an analog signal from the current transformer enters the voltage/frequency conversion sub-unit, the first voltage sampling signal and the analog signal from the current transformer are respectively converted into corresponding first frequency signal and second frequency signal, and the current signal output terminal and the voltage signal output terminal 31 respectively acquires frequency signals representing a voltage value and a current value from the circuit board.

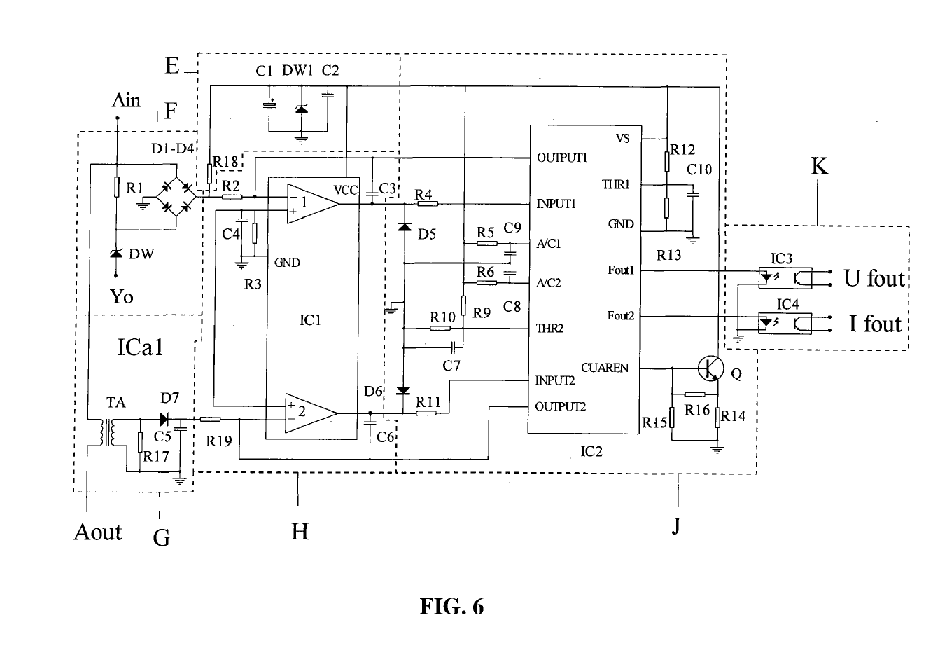

As shown in FIG. 6, a voltage and current sampling device of a second embodiment of the invention is almost the same as the first embodiment, except that:

The voltage signal processing circuit comprises a first voltage circuit operating to process the real-time voltage signal whereby generating the first voltage sampling signal, and a second voltage circuit operating to process current from the current transformer TA.

The first voltage circuit comprises a first resistor R1, a first voltage stabilizing tube DW, a rectifier bridge D1-D4, the first voltage stabilizing tube DW is serially connected to the first resistor R1, the rectifier bridge D1-D4 is parallel connected to the first resistor R1, the real-time voltage signal is output from both ends of the first resistor R1, and the rectifier bridge D1-D4 operates to output the first voltage sampling signal.

The second voltage circuit comprises a resistor R17 parallel connected to an output end of the current transformer TA, and further operates to parallel connect the fifth capacitor C5 and a diode D7 to the output end of the current transformer TA whereby converting the current signal into a second voltage sampling signal.

The power circuit comprises a fourth resistor R18, a second voltage stabilizing tube DW1, a first capacitor C1, and a second capacitor C2, the fourth resistor R18 is serially connected to an anode of the rectifier bridge D1-D4 whereby reducing voltage, and the second voltage stabilizing tube DW1, the first capacitor C1, and the second capacitor C2 are parallel connected whereby implementing voltage stabilizing and filtering, and forming stabilized power output.

The integrating circuit comprises a first integrator, a second integrator, a delay circuit, and a feedback circuit.

An inverting input end of the first integrator IC1 is connected to an anode of the rectifier bridge D1-D4 via a second resistor R2 whereby acquiring the first voltage sampling signal, and an output end of the power circuit E is connected to an end VCC of the integrating circuit whereby providing operating voltage thereto.

An inverting input end of the second integrator is connected to an output end of the rectifier bridge via a resistor R19 whereby acquiring the second voltage sampling signal.

The delay circuit comprises a fifth resistor R3 and a third capacitor C4 parallel connected to each other, one parallel connection end is connected to a non-inverting input end of each of the first integrator and the second integrator, and the other parallel connection end is connected to the ground.

The feedback circuit comprises a fourth capacitor C3, a first diode D5, a fifth capacitor C6, and a second diode D6.

The fourth capacitor C3 is serially connected to the first diode D5, whereby preventing signal drift at an output end of the first integrator.

The fifth capacitor C6 is serially connected to the second diode D6, whereby preventing signal drift at an output end of the second integrator.

The first diode D5 is serially connected to an anode of the second diode D6, and then to the ground, a connection point of the first diode D5 and the fourth capacitor C3 is connected to an output end of the first integrator, and a connection point of the second diode D6 and the fifth capacitor C6 is connected to an output end of the second integrator.

The voltage/frequency conversion circuit 32 comprises a voltage/frequency conversion chip IC2 with at least two input ends INPUT1 and INPUT 2, a reference voltage generating circuit, and an optoelectronic isolating device.

The input end INPUT1 is connected to an output end of the first integrator via the resistor R4, and the input end INPUT2 is connected to an output end of the second integrator via the resistor R11, whereby respectively acquiring the first current signal and the second current signal, and the power circuit provides operating voltage thereto.

The reference voltage generating circuit comprises a first triode Q, a sixth resistor R16, and a seventh resistor R14. A collecting electrode of the first triode Q is connected to the power circuit, and a base electrode thereof is connected to a reference voltage output end CUAREN of the voltage/frequency conversion chip IC2. The sixth resistor R16 is serially connected to the seventh resistor R14, one serial connection end is connected to the base electrode of the first triode Q, and the other end is connected to the ground, and a connection point of the sixth resistor R16 and the seventh resistor R14 is connected to an emitting electrode of the first triode Q.

The optoelectronic isolating device is connected to output ends FOUT1 and FOUT2 of the voltage/frequency conversion chip IC2, and operates to output a first frequency signal representing voltage, and a second frequency signal representing current. In this embodiment, the optoelectronic isolating device comprises a pair of photo couplers IC3 and IC4.

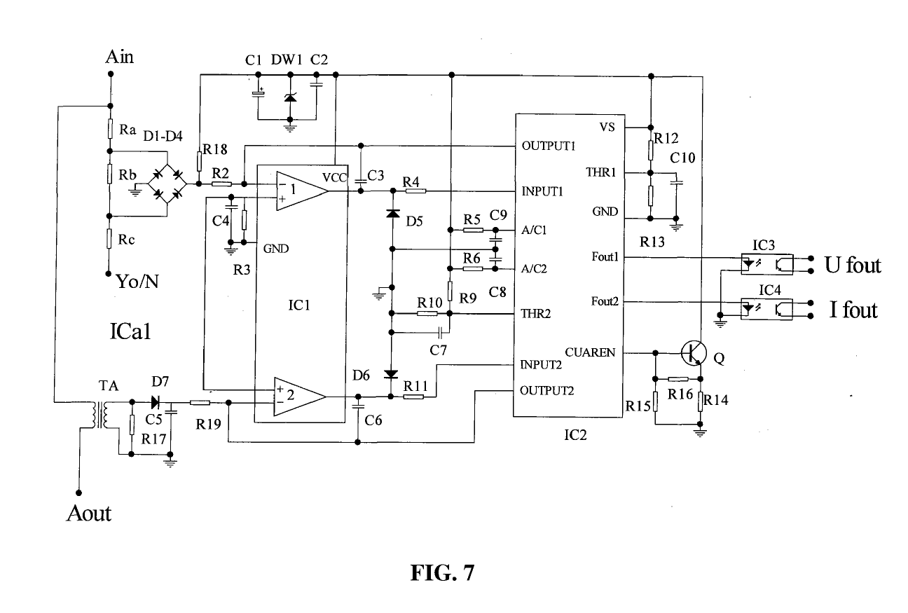

As shown in FIG. 7, a voltage and current sampling device of a third embodiment of the invention is almost the same as the second embodiment, except that the first voltage circuit comprises at least two groups of first resistors serially connected to each other (for example, three groups of resistors Ra, Rb, and Rc are used herein), a rectifier bridge D1-D4 parallel connected to one of the first resistors (Rb), the voltage signal is output from both ends of the first resistor Rb, and the rectifier bridge D1-D4 outputs the first voltage sampling signal.

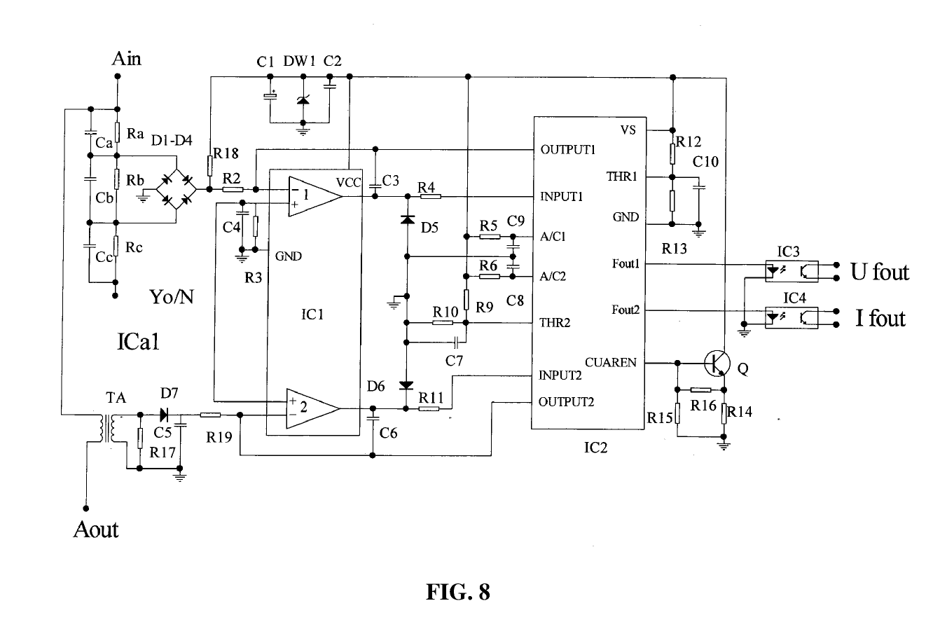

As shown in FIG. 8, a voltage and current sampling device of a fourth embodiment of the invention is almost the same as the second embodiment, except that the first voltage circuit comprises at least two groups each comprising a first resistor and a capacitor parallel connected to each other (for example, three resistors Ra, Rb, and Rc are respectively parallel connected to capacitors Ca, Cb and Cc), a rectifier bridge D1-D4 parallel connected to one of the groups Rb and Cc, the voltage signal is output from both ends of the first resistor Rb and the capacitor Cb, and the rectifier bridge D1-D4 outputs the first voltage sampling signal.

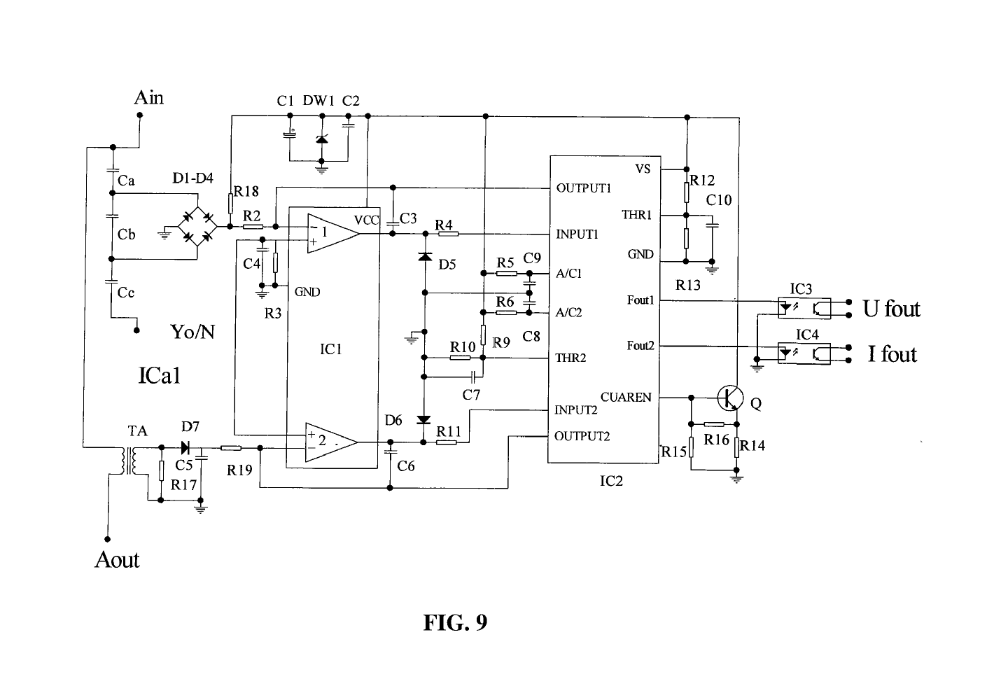

As shown in FIG. 9, a voltage and current sampling device of a fifth embodiment of the invention is almost the same as the second embodiment, except that the first voltage circuit comprises at least two groups of capacitors serially connected to each other (for example, three groups of capacitors Ca, Cb and Cc are serially connected), a rectifier bridge D1-D4 parallel connected to one of the groups Cb, the voltage signal is output from both ends of the capacitor Cb, and the rectifier bridge D1-D4 outputs the first voltage sampling signal.

The above-mentioned first voltage circuit and the first voltage circuit in FIG. 3 can be changed by each other, and the process will not be described hereinafter.

While particular embodiments of the invention have been shown and described, it will be obvious to those skilled in the art that changes and modifications may be made without departing from the invention in its broader aspects, and therefore, the aim in the appended claims is to cover all such changes and modifications as fall within the true spirit and scope of the invention.

The invention claimed is:

1. A voltage and current sampling device, comprising
a box;
a current transformer; and
a voltage acquisition unit; comprising a voltage collection sub-unit, and a voltage/frequency conversion sub-unit;
wherein
said current transformer is disposed in said box;
a phase line passes through the center of said current transformer;
said current transformer outputs a current signal via a current signal output end;
said voltage collection sub-unit is disposed on said phase line whereby acquiring a real-time voltage signal and converting said real-time voltage signal into a first voltage sampling signal; and
said voltage/frequency conversion sub-unit is connected to said voltage collection sub-unit whereby converting said first voltage sampling signal into a first frequency signal.

2. The voltage and current sampling device of claim 1, further comprising a voltage conversion unit connected to said current signal output end whereby the voltage conversion unit converts output current into a second voltage sampling signal.

3. The voltage and current sampling device of claim 2, wherein said voltage/frequency conversion sub-unit further operates to convert said second voltage sampling signal into a second frequency signal.

4. The voltage and current sampling device of claim 1, wherein
said voltage collection sub-unit comprises a voltage sampling portion, a voltage signal processing circuit; and a power circuit;
said voltage sampling portion operates to collect a real-time voltage signal on said phase line;
said voltage signal processing circuit operates to rectify said real-time voltage signal and to convert said real-time voltage signal into a first DC voltage sampling signal; and
said power circuit operates to stabilize and filter said first DC voltage sampling signal, and to transform said first DC voltage sampling signal into power voltage.

5. The voltage and current sampling device of claim 4, wherein
said voltage sampling portion is a mechanical component, and comprises a conductive sampling sub-portion; and a fixing sub-portion;
said conductive sampling sub-portion is made of conductive materials, and connected to said power line, or contacted with a core of said power line via an insulation slug, whereby acquiring said real-time voltage signal on said power line; and
said fixing sub-portion operates to fix connection between said conductive sampling sub-portion and said power line.

6. The voltage and current sampling device of claim 5, wherein as said power line has said insulation slug, said conductive sampling sub-portion is in the shape of a tooth, penetrates in said power line and is contacted with said core thereof.

7. The voltage and current sampling device of claim 4, wherein
said voltage signal processing circuit comprises a first voltage circuit operating to process said real-time voltage signal whereby generating said first voltage sampling signal;
said first voltage circuit comprises a first resistor, a first voltage stabilizing tube, a rectifier bridge;
said first voltage stabilizing tube is serially connected to said first resistor;
said rectifier bridge is parallel connected to said first resistor;
said real-time voltage signal is output from both ends of said first resistor; and
said rectifier bridge operates to output said first voltage sampling signal.

8. The voltage and current sampling device of claim 7, wherein
said power circuit comprises a fourth resistor, a second voltage stabilizing tube, a first capacitor, and a second capacitor;
said fourth resistor is serially connected to said rectifier bridge whereby reducing voltage; and
said second voltage stabilizing tube, said first capacitor, and said second capacitor are parallel connected whereby implementing voltage stabilizing and filtering, and forming stabilized power output.

9. The voltage and current sampling device of claim 4, wherein
said voltage signal processing circuit comprises a first voltage circuit operating to process said real-time voltage signal whereby generating said first voltage sampling signal;
said first voltage circuit comprises at least a pair of first resistors, and a rectifier bridge;
said first resistors are serially connected to each other; and
said rectifier bridge is parallel connected to one of said first resistors, and operates to output said first voltage sampling signal.

10. The voltage and current sampling device of claim 4, wherein
said voltage signal processing circuit comprises a first voltage circuit operating to process said real-time voltage signal whereby generating said first voltage sampling signal;
said first voltage circuit comprises a first resistors, at least a pair of groups each comprising a first resistor and a capacitor, and a rectifier bridge;
said groups are serially connected to each other; and
said rectifier bridge is parallel connected to one of said groups, and operates to output said first voltage sampling signal.

11. The voltage and current sampling device of claim 4, wherein
said voltage signal processing circuit comprises a first voltage circuit operating to process said real-time voltage signal whereby generating said first voltage sampling signal;
said first voltage circuit comprises a first resistors, at least a pair of capacitors, a rectifier bridge;
said capacitors are serially connected to each other; and
said rectifier bridge is parallel connected to one of said capacitors, and operates to output said first voltage sampling signal.

12. The voltage and current sampling device of claim 1, wherein
said voltage/frequency conversion sub-unit comprises an integrating circuit, and a voltage/frequency conversion circuit;
said integrating circuit operates to integrate voltage of said first voltage sampling signal, and to convert said first voltage sampling signal into corresponding first current; and
said voltage/frequency conversion circuit operates to receive said first current, and to output a first frequency corresponding to said voltage of said first voltage sampling signal.

13. The voltage and current sampling device of claim 12, wherein
said integrating circuit comprises a first integrator;
an inverting input end of said first integrator acquires said first voltage sampling signal; and
said power circuit provides operating voltage to said integrator.

14. The voltage and current sampling device of claim 13, wherein
said integrating circuit further comprises a fifth resistor, a third capacitor, a fifth capacitor, and a second diode;
said fifth resistor is parallel connected to said third capacitor, one parallel connection end is connected to a non-inverting input end of said second integrator, and the other parallel connection end is connected to the ground;
said fifth capacitor is serially connected to said second diode whereby preventing signal drift at an output end of said second integrator;
an anode of said second diode is connected to the ground; and
a connection point of said second diode and said fifth capacitor is connected to an output end of said first integrator.

15. The voltage and current sampling device of claim 3, wherein
said voltage/frequency conversion sub-unit comprises an integrating circuit, and a voltage/frequency conversion circuit;
said integrating circuit operates to integrate voltage of said first voltage sampling signal and said second voltage sampling signal, and to respectively convert said first voltage sampling signal and said second voltage sampling signal into corresponding first current and second current; and
said voltage/frequency conversion circuit operates to receive said first current and said second current, and to output a first frequency and a second frequency respectively corresponding to said voltage of said first voltage sampling signal and said second voltage sampling signal.

16. The voltage and current sampling device of claim 15, wherein
said integrating circuit comprises a first integrator, and a second integrator;
an inverting input end of said first integrator acquires said first voltage sampling signal;
an inverting input end of said second integrator acquires said second voltage sampling signal; and
said power circuit provides operating voltage to said integrator and said second integrator.
